(19) United States
(12) Patent Application Publication
(10) Pub. No.: US 2023/0234603 A1
(43) Pub. Date: Jul. 27, 2023

(54) INFORMATION PROCESSING SYSTEM, INFORMATION PROCESSING METHOD, AND PROGRAM

(71) Applicant: TOYOTA JIDOSHA KABUSHIKI KAISHA, Toyota-shi Aichi-ken (JP)

(72) Inventor: Ippei NISHITANI, Toyota-shi Aichi-ken (JP)

(73) Assignee: TOYOTA JIDOSHA KABUSHIKI KAISHA, Toyota-shi Aichi-ken (JP)

(21) Appl. No.: 18/098,224

(22) Filed: Jan. 18, 2023

(30) Foreign Application Priority Data
Jan. 27, 2022 (JP) 2022-011027

(51) Int. Cl. B60W 50/14; G07C 5/08

(52) U.S. Cl. CPC B60W 50/14; G07C 5/0816; B60W 60/001

(57) ABSTRACT

An information processing system, an information processing method, and a program that present simulation results so that users can easily examine defect data are provided. An information processing device includes an acquisition unit configured to acquire a plurality of simulation data pieces corresponding to a plurality of simulation conditions, respectively, or a plurality of experimental data pieces corresponding to a plurality of experimental conditions, respectively, a data extraction unit configured to extract a plurality of defect data pieces from the plurality of simulation data pieces or the plurality of experimental data pieces, a classification unit configured to classify the plurality of defect data pieces into a plurality of groups based on feature data calculated from each of the plurality of defect data pieces, and a presentation unit configured to visualize representative data extracted from each group and present the visualized representative data to the user.

### CROSS REFERENCE TO RELATED APPLICATIONS

This application is based upon and claims the benefit of priority from Japanese patent application No. 2022-011027, filed on Jan. 27, 2022, the disclosure of which is incorporated herein in its entirety by reference.

### BACKGROUND

The present disclosure relates to an information processing system, method, and program, and in particular to a technique for presenting simulation or experimental results to users.

Japanese Patent No. 6082759 discloses an information processing system that displays simulation results.

### SUMMARY

Result data showing results of simulations or experiments may include result data (defect data) for defect cases that do not meet system requirements. In such a case, an information processing system that presents simulation results is desired so that a user can easily examine defect data.

The present disclosure has been made to solve such a problem and an object thereof is to provide an information processing system, an information processing method, and a program that present simulation results or experimental results so that users can easily examine defect data.

In an example aspect of an embodiment, an information processing system includes:
an acquisition unit configured to acquire a plurality of simulation data pieces corresponding to a plurality of simulation conditions, respectively, or a plurality of experimental data pieces corresponding to a plurality of experimental conditions, respectively;
an extraction unit configured to extract a plurality of defect data pieces from the plurality of simulation data pieces or the plurality of experimental data pieces;
a classification unit configured to classify the plurality of defect data pieces into a plurality of groups based on feature data calculated from each of the plurality of defect data pieces; and
a presentation unit configured to visualize representative data extracted from each group and present the visualized representative data to the user.

In another example aspect of an embodiment, an information processing method performed by a computer includes:
acquiring a plurality of simulation data pieces corresponding to a plurality of simulation conditions, respectively, or a plurality of experimental data pieces corresponding to a plurality of experimental conditions, respectively;
extracting a plurality of defect data pieces from the plurality of simulation data pieces or the plurality of experimental data pieces;
classifying the plurality of defect data pieces into a plurality of groups based on feature data calculated from each of the plurality of defect data pieces; and
visualizing representative data extracted from each group and presenting the visualized representative data to the user.

In another example aspect of an embodiment, a program causes a computer to execute an information processing method including:
acquiring a plurality of simulation data pieces corresponding to a plurality of simulation conditions, respectively, or a plurality of experimental data pieces corresponding to a plurality of experimental conditions, respectively;
extracting a plurality of defect data pieces from the plurality of simulation data pieces or the plurality of experimental data pieces;
classifying the plurality of defect data pieces into a plurality of groups based on feature data calculated from each of the plurality of defect data pieces; and
visualizing representative data extracted from each group and presenting the visualized representative data to the user.

According to the present disclosure, it is possible to provide an information processing system, an information processing method, and a program that present simulation results or experimental results so that users can easily examine defect data.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a block diagram showing a configuration of an information processing device according to a first embodiment;

FIG. 2 is a flowchart showing a flow of information processing method according to the first embodiment;

FIG. 3 is an overview diagram showing an overview of a passing simulation of robots;

FIG. 4 is an overview diagram showing departure points and destination points of the robots;

FIG. 5 is an overview diagram showing an overview of a search-based test;

FIG. 6 is an overview diagram showing an overview of a method for extracting feature data;

FIG. 7 is an overview diagram showing an example of a screen for displaying representative data; and

FIG. 8 is an overview diagram showing an example of a screen for displaying clustering results.

### DESCRIPTION OF EMBODIMENTS

Hereinafter, the present disclosure will be described through the embodiments of the disclosure, but the disclosure set forth in the claims is not limited to the following embodiments. Further, not all of the configurations described in the embodiment are necessary to solve the problem.

### First Embodiment

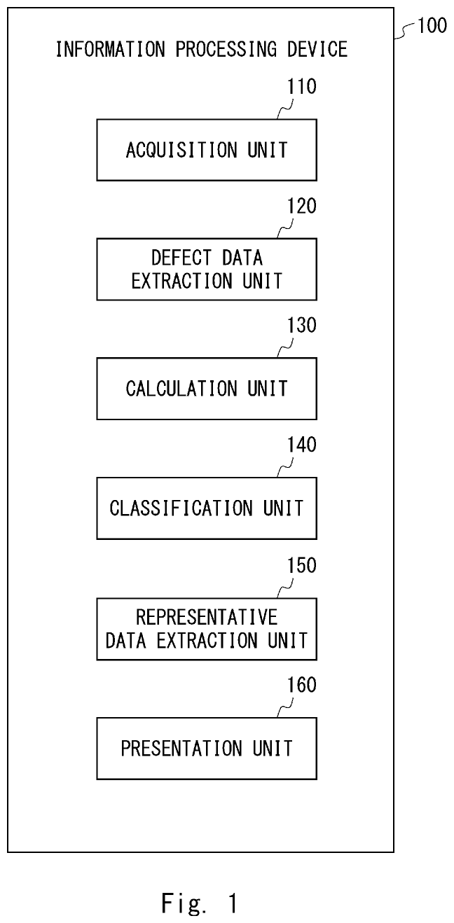

Hereinafter, an information processing device according to a first embodiment will be described with reference to the drawings. FIG. 1 is a block diagram showing a configuration of an information processing device 100 according to a first embodiment. The information processing device 100 is an example of an information processing system. The information processing device 100 may be an edge terminal. A system in which processing is completed within an edge terminal can also be included in an information processing system. As will be discussed lastly, the information processing system may include a server.

The information processing device 100 includes an acquisition unit 110, a defect data extraction unit 120, a calculation unit 130, a classification unit 140, a representative data extraction unit 150, and a presentation unit 160. The information processing device 100 further includes a processor and a memory (not shown). When the processor executes a program, the information processing device 100 functions as the acquisition unit 110, the defect data extraction unit 120, the calculation unit 130, the classification unit 140, the representative data extraction unit 150, and the presentation unit 160.

The acquisition unit 110 acquires a plurality of simulation data pieces corresponding to a plurality of simulation conditions, respectively, or a plurality of experimental data pieces corresponding to a plurality of experimental conditions, respectively. Hereinafter, a case in which the acquisition unit 110 acquires the plurality of simulation data pieces is mainly described. Alternatively, the acquisition unit 110 may acquire real world experimental data instead of the simulation data. Defect data is included in the plurality of simulation data pieces. The defect data is extracted by the defect data extraction unit 120 described later.

The acquisition unit 110 may conduct a search-based test for the purpose of searching for data (defect data) that violates the system requirements to thereby extract the plurality of simulation data pieces. This enables a user to efficiently analyze the defect data. The acquisition unit 110 may receive information as a result of the search-based test regarding whether or not each simulation data piece satisfies the system requirements. The search-based test enables an efficient search for violation of the system requirements by optimization.

The acquisition unit 110 may conduct tests other than the search-based test. The acquisition unit 110 may, for example, conduct a test in which simulation conditions are set at equal intervals (e.g., grid test) or a test in which the user sets the simulation conditions optionally.

Specifically, the acquisition unit 110 acquires the simulation data related to a plurality of mobile bodies (e.g., robot 1, robot 2, and robot 3). In such a case, a departure point and time of each mobile body may be set as the simulation conditions. For example, the defect data extraction unit 120 described later can regard, as success data, simulation data in which a predetermined mobile body reaches its destination point by a target time (e.g., 120 seconds after the start of the simulation) and other data as defect data.

Hereinafter, a case in which the acquisition unit 110 acquires simulation data related to movements of a plurality of mobile bodies will be mainly described. However, the data acquired by the acquisition unit 110 is not limited to the data related to the movement of the mobile body. The data acquired by the acquisition unit 110 may be used to examine whether an operation of a control system meets the system requirements under various conditions. The controls subjected to simulation may be, for example, engine control, merging control of automatic driving vehicles, or smart grid control.

In the case of engine control, the acquisition unit 110 acquires data (e.g., an input trajectory of an accelerator and a brake) for examining an amount of divergence between a target vehicle speed and an actual vehicle speed under the input conditions to the accelerator and the brake. In the case of merging control of automatic driving vehicles, the acquisition unit 110 acquires data (e.g., movement trajectories of the automatic driving vehicles) for examining collisions of the automatic driving vehicles for various initial positions. In the case of smart grid control, the acquisition unit 110 acquires data (e.g., an amount of electricity used or generated) for examining excess or deficiency of electricity in each facility under various supply and demand conditions.

As described above, the defect data extraction unit 120 extracts a plurality of the defect data pieces from the plurality of simulation data pieces or the plurality of experimental data pieces. Hereinafter, the defect data extraction unit 120 may be referred to simply as an extraction unit. The simulation data pieces related to the movements of the plurality of mobile bodies may include the plurality of defect data pieces originating from a degree of freedom of movement of each of the plurality of mobile bodies. Specifically, when a mobile body passes another mobile body, it may collide with it, stop, or take an unnecessary detour.

More specifically, the defect data extraction unit 120 defines the simulation data violating the system requirements as the defect data. The system requirements may be optionally determined by the user. The system requirements may be, for example, that a predetermined mobile body reaches its destination point within a predetermined time. Information about whether the system requirements are violated may be included in a result of a search-based test. The defect data may be determined based on a threshold or depending on whether a condition expressed in the form of STL (Signal Temporal Logic) is met.

Note that the defect data extraction unit 120 may extract the defect data based on a request of a subsystem instead of a request of an entire system. For example, a system requirement that a plurality autonomous mobile bodies reach their destination points in time may include a subsystem requirement that an error of position estimation for each autonomous mobile body be less than or equal to a threshold. In such a case, the defect data extraction unit 120 can define, as the success data, simulation data in which an error of position estimation for autonomous mobile body is less than or equal to the threshold, and simulation data other than the success data as the defect data.

The calculation unit 130 calculates feature data from each of the plurality of defect data pieces. The feature data is also referred to as a feature parameter. The feature data is used to determine a similarity between the defect data pieces when the classification unit 140 described later performs clustering. The calculation unit 130 may, for example, extract position coordinates (e.g., x coordinate of the robot 1, y coordinate of the robot 1, x coordinate of the robot 2, y coordinate of the robot 2, x coordinate of the robot 3, and y coordinate of the robot 3) of the plurality of mobile bodies at each of a plurality of time points (e.g., 0 second, 12 seconds, 24 seconds, 36 seconds, 48 seconds, 60 seconds, 72 seconds, 84 seconds, 96 seconds, 108 seconds, and 120 seconds after a start of the simulation) and calculate feature data by arranging (coupling) the extracted position coordinates.

Note that the calculation unit 130 may use univariate data (e.g., velocity data of the robot 1) instead of multivariate data as the feature data. The calculation unit 130 may use data other than time-series data (e.g., x and y coordinates of a final position of each robot) as the feature data.

The method for calculating the feature data is not limited to the method described above for extracting and coupling data values at a plurality of time points. The calculation unit 130 may calculate the feature data by using techniques such as sparse coding, wavelet transformation, shapelet transformation, singular spectrum decomposition, and non-negative matrix factorization.

The classification unit 140 classifies the plurality of defect data pieces into a plurality of groups based on the feature data calculated from each of the plurality of defect data pieces. The classification unit 140 groups similar defect data pieces by clustering. The clustering is performed, for example, by implementing the Ward's method. The number of clusters may be set by the user or determined automatically based on an index of a distance between clusters or a similarity of the data in the clusters.

The clustering method performed by the classification unit 140 is not limited to the Ward's method. Hierarchical clustering using a distance index different from the distance index used in the Ward's method may be performed. Non-hierarchical clustering such as k-means or DBSCAN (Density-Based Spatial Clustering of Applications with Noise) may also be performed.

The representative data extraction unit 150 extracts representative data from each group. The representative data, also referred to as core data, indicates core data of each group. Specifically, the representative data extraction unit 150 sets all the data pieces in each group as candidates for the representative data, performs processing to take a difference (error) between the candidate and each of the other data pieces in the group, and calculates an average value of the differences (also called an ambient error). The ambient error is also called an error mean. Next, the representative data extraction unit 150 determines the candidate with the smallest ambient error as the representative data.

The representative data extraction unit 150 may also extract the representative data based on a median or a center of gravity of the data pieces in each group. The representative data extraction unit 150 may also extract the representative data based on the degree of defect of the data in each group. For example, the representative data extraction unit 150 may use data with the greatest degree of defect as the representative data.

The presentation unit 160 visualizes the representative data extracted from each group and presents the visualized representative data to the user. Thus, the user can easily understand the entire defect data. The presentation unit 160 may further present the classification result (clustering data) obtained by the classification unit 140. This allows the user to determine whether the classification is done appropriately and to handle the defect data accurately. At this time, the presentation unit 160 may highlight the data with a large difference from the representative data (e.g., data with an ambient error greater than or equal to a threshold) for each group. Data with a large difference from the representative data is considered to be data that needs to be checked by the user, thus preventing data from being overlooked. In addition to the representative data and classification result, the presentation unit 160 may further present a list of defect data. The users can check original data of the defect data if necessary.

When the presentation unit 160 presents the result, it does not need to display all of the original data, the clustering results, and the representative data of the defect data. The presentation unit 160 may present only the data required by the user. Furthermore, the representative data to be presented is not limited to signal data that varies over time. The representative data may be information related to an ID of the extracted representative data, for example, a video or a chart other than signal data.

The presentation unit 160 may display a display screen on a display device such as a display not shown. The user can check the display screen to specify a cause of a defect, fix the system, and the like.

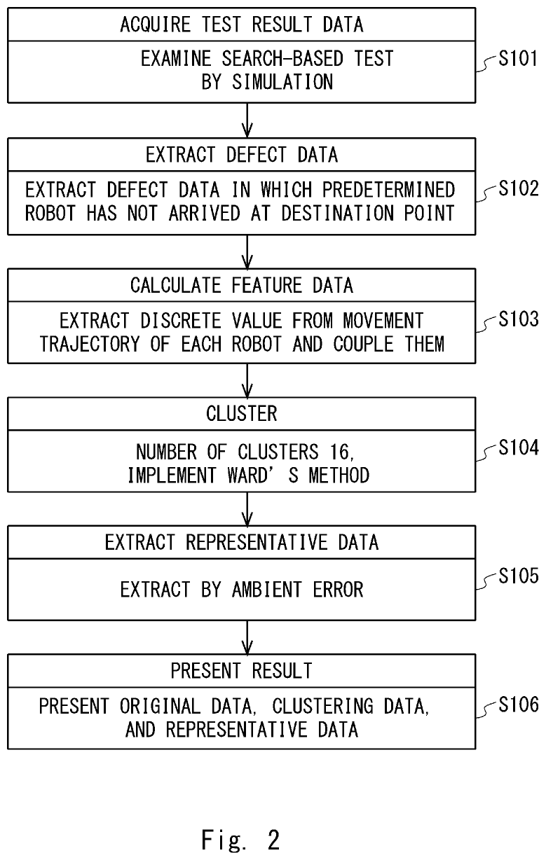

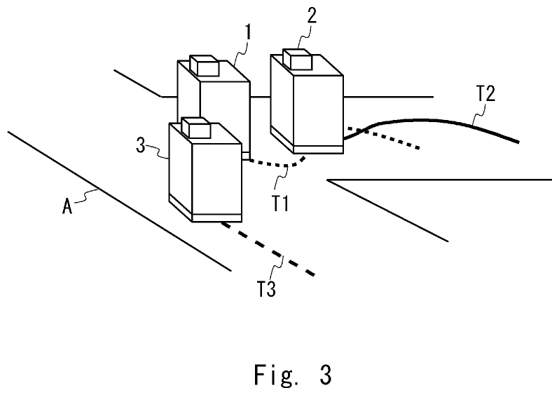

Next, an information processing method according to the first embodiment will be explained with reference to FIG. 2. Specifically, a case where a search-based test examination is conducted by simulating passing of three robots will be described. FIG. 3 is an overview diagram showing an overview of the simulation. The robots 1, 2, and 3 pass each other in a T-shaped passage (curve) A. The sign T1 indicates a movement trajectory of the robot 1, the sign T2 shows a movement trajectory of the robot 2, and the sign T3 indicates movement trajectory of the robot 3.

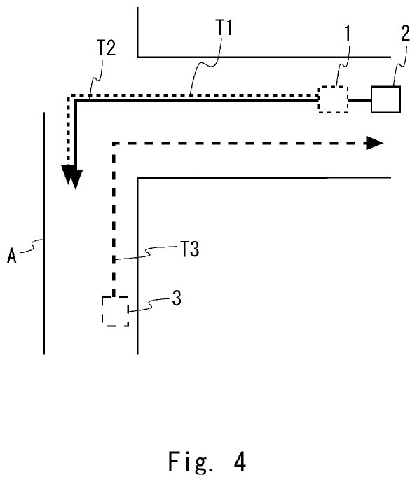

The departure and destination points of the robots 1, 2, and 3 will be described with reference to FIG. 4. The positions of the robots 1, 2, and 3 indicate the departure points of the robots 1, 2, and 3. The sign T1 schematically indicates the movement trajectory of the robot 1, and a tip of the arrow indicates the destination point of the robot 1. The sign T2 schematically indicates the movement trajectory of the robot 2, and a tip of the arrow indicates the destination point of the robot 2. The sign T3 schematically indicates the movement trajectory of the robot 3, and a tip of the arrow indicates the destination point of the robot 3.

A simulation time is 120 seconds and the time is expressed as t=0 to 120 [s]. A departure time of the robot 1 is fixed at t=16 [s]. A departure time of the robot 2 is selected from a time between t=16 [s] and t=26 [s]. A departure time of the robot 3 is selected from a time between t=7 [s] and t=37 [s].

The system requirements are that the robot 1 or the robot 2 reaches its destination point within 120 seconds, and further, the robot 3 reaches its destination point within 120 seconds. The inventor has conducted a search-based test to search for scenarios that would violate the system requirements and performed 500 simulations.

The departure time of the robot 2 and the departure time of the robot 3 correspond to the simulation conditions. Assume that the horizontal axis is the departure time of the robot 2 and the vertical axis is the departure time of the robot 3, the points corresponding to the 500 simulation conditions can be plotted. In search-based tests, the distance between adjacent points is generally not constant. In grid tests, on the other hand, the distance between adjacent points is generally constant. A search-based test enables a search for defect data more efficiently than a grid test.

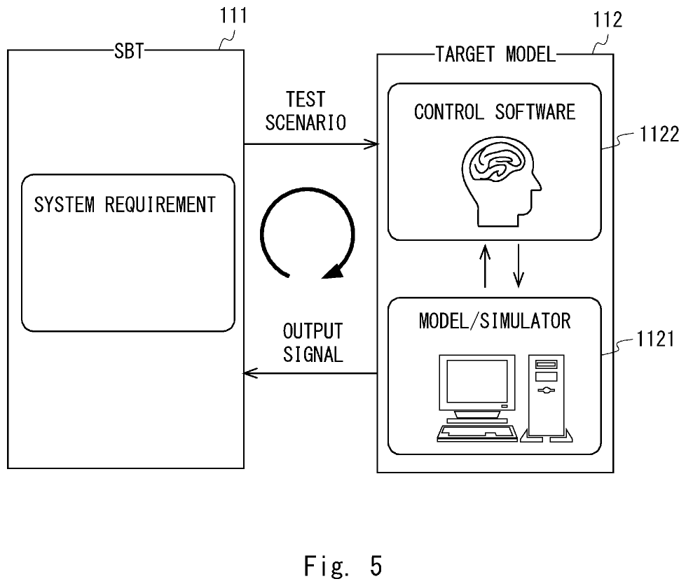

FIG. 5 is an overview diagram showing an overview of the search-based test. A system shown in FIG. 5 includes a SBT (Search-based Testing) unit 111 and a target model 112. The acquisition unit 110 of the information processing device 100 may include the SBT unit 111 and the target model 112.

The SBT unit 111 conducts a search-based test by using the target model 112. The target model 112 includes a model/simulator 1121 and control software 1122 to control the model/simulator.

The aforementioned system requirements are set in the SBT unit 111, and a test scenario is input to the SBT unit 111. The test scenario includes the simulation conditions. The target model 112 receives the test scenario and returns an output signal indicating the simulation result. The output signal may include a signal indicating a time in the position coordinate of the robot 1 over time, a signal indicating a change in the position coordinate of the robot 2 over time, and a signal indicating a change in the position coordinate of the robot 3 over time.

Returning to FIG. 2, the information processing method according to the first embodiment is explained. First, the acquisition unit 110 of the information processing device 100 acquires a result of the search-based test examination by simulation (Step S101). Next, the defect data extraction unit 120 of the information processing device 100 extracts a plurality of defect data pieces (e.g., data where a predetermined robot has not arrived at its destination point) from 500 simulation data pieces (Step S102). Assume that the 500 simulation data pieces described above includes 134 defect data pieces. The problem is that it requires a lot of man-hours to understand all the defect events from the 134 defect data pieces. On the other hand, the 134 defect data pieces includes many pieces of similar data. Therefore, it is desirable to remove similar data to understand a defect event.

Next, the calculation unit 130 of the information processing device 100 calculates feature data from each of the 134 defect data pieces (Step S103). Specifically, the calculation unit 130 extracts position information (also referred to as discrete values) at each of a plurality of discrete time points from the movement trajectory of each robot, and calculates the feature data by arranging (coupling) them.

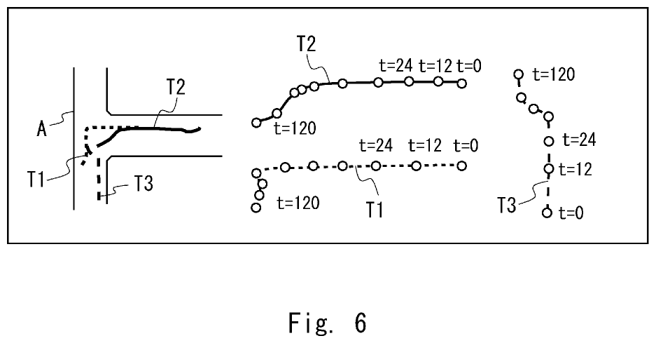

FIG. 6 is a diagram for explaining an example of the feature data. The left side of FIG. 6 shows an example of the simulation data, where the sign T1 indicates the movement trajectory of the robot 1, the sign T2 indicates the movement trajectory of the robot 2, and the sign T3 indicates the movement trajectory of the robot 3. The horizontal direction in FIG. 6 indicates an x direction, and the x coordinate increases toward the right side. The vertical direction in FIG. 6 indicates a y direction, and the y coordinate increases toward the top.

On the right side of FIG. 6, the movement trajectory T1 of the robot 1, the movement trajectory T2 of the robot 2, and the movement trajectory T3 of the robot 3 are enlarged. Each open circle indicates the position of the robot at each time point (t=0, t=12, t=24, . . . , t=120). In some cases, the open circles are omitted for better visibility. If the robots are stopped, the open circles may overlap.

The calculation unit 130 calculates the feature data by extracting and coupling the (x, y) coordinates of the robot 1, the (x, y) coordinates of the robot 2, and the (x, y) coordinates of the robot 3 at each time point. The feature data retains time series and multivariate correlation properties in an output signal. When the (x, y) coordinates of each robot are extracted every 12 seconds, the (x, y) coordinates of the three robots are extracted at 11 time points, so the dimension of the feature data is 3×2×11=66 dimensions.

Returning to FIG. 2, the explanation is continued. Next, the classification unit 140 of the information processing device 100 clusters the 134 defect data pieces based on the feature data of each of the 134 defect data pieces (Step S104). Specifically, the classification unit 140 specifies the number of clusters as 16 and performs clustering by the Ward's method. The number of clusters is set to a number that is easy for users to check.

Next, the representative data extraction unit 150 of the information processing device 100 extracts the representative data from each of the 16 groups (Step S105). The representative data may be, for example, data with the smallest mean value of the difference (ambient error) with each of the other data in the group.

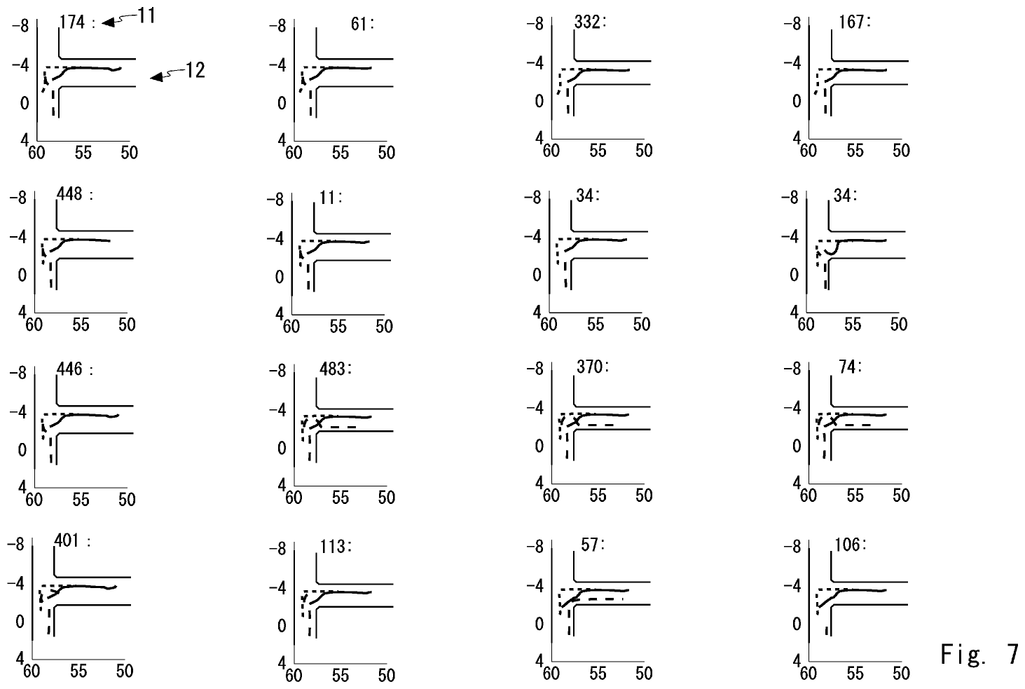

Next, the presentation unit 160 of the information processing device 100 visualizes the 134 pieces of original data, the clustering data, and the representative data extracted from each group and presents them to the user (Step S106). FIG. 7 shows an example of a screen displaying representative data. FIG. 7 shows 16 pieces of the representative data. Each piece of the representative data includes an ID 11 for identifying the simulation data and a graph 12 showing the movement trajectory of each robot. In addition to the graph 12, video and other data may be further associated with the ID 11.

The graph 12 includes a shape of the T-shaped passage, the movement trajectory of the robot 1, the movement trajectory of the robot 2, and the movement trajectory of the robot 3. The horizontal axis of the graph 12 indicates the x direction, and the vertical axis of the graph 12 indicates they direction.

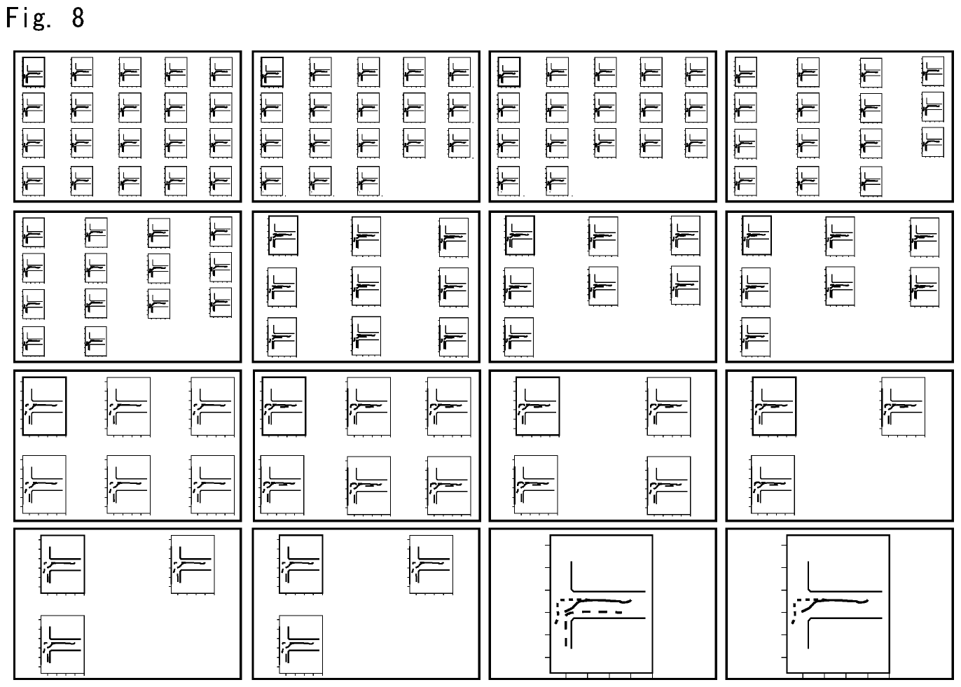

FIG. 8 shows the classification result (clustering data) obtained by the classification unit 140. The 134 defect data pieces are classified into 16 groups. Each group is surrounded by a frame. The data at the head of each group indicates the representative data. The representative data may be highlighted using, for example, a red frame. In addition, the defect data within each group may be arranged in descending order of the aforementioned ambient errors.

As already mentioned, data with a large difference from the representative data (e.g., data with an ambient error greater than or equal to a threshold) may be highlighted. For example, data with a large difference from the representative data may be highlighted using a blue frame or the like. Data may be overlooked when the representative data is extracted, but users can see data with a large ambient error on the presented screen.

The user can check the information presented by the presentation unit 160. Based on the information presented, the user specifies data related to a defect event to be addressed. If the user cannot specify a cause of the defect only by the trajectory of each robot, he/she may check the video associated with the ID 11 or a flag (e.g., a flag to indicate whether a robot has collided).

Lastly, the effects of the information processing device according to the first embodiment will be described. Simulations and experimental tests are sometimes conducted with the aim of examining that control systems are created as required by developers. If a test result includes defect data, the developer is required to check the behavior of the system, determine the need for a fix, determine a cause of the defect, and fix the system.

When a plurality of defect data pieces are present, if the events associated with individual defect data pieces are fixed in order, it is possible that an approach to one defect event may contradict an approach to another defect event. Therefore, in order to fix the event effectively, in some embodiments, an approach is considered in which a developer sees a plurality of defect events simultaneously and resolves them simultaneously. However, when there is a large amount of defect data, it requires a lot of man-hours to analyze them. On the other hand, if defect data is randomly extracted in order to reduce the number of defect data pieces to be checked, there is a risk that defect events may be overlooked.

By clustering and extracting the representative data (core data) for a large amount of defect data, the information processing device according to the first embodiment can significantly reduce the amount of defect data checked by developers while reducing the number of overlooked defect events. This enables users to efficiently and effectively detect defect events and reduce the time required to fix the system.

According to the information processing device of the first embodiment, the user can only see defect data. If the display includes normal data, there is a possibility that defect data may be overlooked. However, according to the first embodiment, this possibility can be reduced. Moreover, by setting the feature data used for clustering, users who do not have expertise in the target control system can also specify a cause of a defect.

The information processing system does not necessarily have a configuration in which all of the functional elements are integrated in the information processing device 100. For example, the function of the representative data extraction unit 150 may be carried by an operation unit provided in a server connected to the information processing device 100 via a network. In this case, the server sends the representative data to the information processing device 100. The presentation unit 160 of the information processing device 100 achieves the same presentation as that in first embodiment by using the sent representative data. In this manner, the information processing system may be configured to include the server and the information processing device 100. The processor or memory described above may be disposed on a server or in both the information processing device 100 and the server.

In the above example, the program includes instructions (or software codes) that, when loaded into a computer, cause the computer to perform one or more of the functions described in the embodiments. The program may be stored in a non-transitory computer readable medium or a tangible storage medium. By way of example, and not a limitation, non-transitory computer readable media or tangible storage media can include a random-access memory (RAM), a read-only memory (ROM), a flash memory, a solid-state drive (SSD) or other types of memory technologies, a CD-ROM, a digital versatile disc (DVD), a Blu-ray disc or other types of optical disc storage, and magnetic cassettes, magnetic tape, magnetic disk storage or other types of magnetic storage devices. The program may be transmitted on a transitory computer readable medium or a communication medium. By way of example, and not a limitation, transitory computer readable media or communication media can include electrical, optical, acoustical, or other forms of propagated signals.

Note that the present disclosure is not limited to the above embodiments and can be modified as appropriate without departing from the purport.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An information processing system comprising:
an acquisition unit configured to acquire a plurality of simulation data pieces corresponding to a plurality of simulation conditions, respectively, or a plurality of experimental data pieces corresponding to a plurality of experimental conditions, respectively;
an extraction unit configured to extract a plurality of defect data pieces from the plurality of simulation data pieces or the plurality of experimental data pieces;
a classification unit configured to classify the plurality of defect data pieces into a plurality of groups based on feature data calculated from each of the plurality of defect data pieces; and
a presentation unit configured to visualize representative data extracted from each group and present the visualized representative data to a user.

2. The information processing system according to claim 1, wherein
the acquisition unit is configured to acquire the simulation data pieces or the experimental data pieces related to movements of a plurality of mobile bodies, and
the extraction unit extracts the plurality of defect data pieces originating from a degree of freedom of the movement of each of the plurality of mobile bodies.

3. The information processing system according to claim 2, further comprising:
a calculation unit configured to extract position coordinates of each of the plurality of mobile bodies at each of a plurality of time points from each of the defect data pieces and calculate the feature data by arranging the extracted position coordinates.

4. The information processing system according to claim 1, wherein
the presentation unit further presents a result of the classification obtained by the classification unit and highlights the defect data piece with a large difference from the representative data for each group.

5. The information processing system according to claim 1, wherein
the acquisition unit acquires the plurality of simulation data pieces by conducting a search-based test for a purpose of searching for data that violates a system requirement, and
the extraction unit extracts the plurality of defect data pieces that violate the system requirement.

6. An information processing method performed by a computer comprising:
acquiring a plurality of simulation data pieces corresponding to a plurality of simulation conditions, respectively, or a plurality of experimental data pieces corresponding to a plurality of experimental conditions, respectively;
extracting a plurality of defect data pieces from the plurality of simulation data pieces or the plurality of experimental data pieces;
classifying the plurality of defect data pieces into a plurality of groups based on feature data calculated from each of the plurality of defect data pieces; and
visualizing representative data extracted from each group and presenting the visualized representative data to a user.

7. A non-transitory computer readable medium storing a program causing a computer to execute an information processing method comprising:
acquiring a plurality of simulation data pieces corresponding to a plurality of simulation conditions, respectively, or a plurality of experimental data pieces corresponding to a plurality of experimental conditions, respectively;
extracting a plurality of defect data pieces from the plurality of simulation data pieces or the plurality of experimental data pieces;
classifying the plurality of defect data pieces into a plurality of groups based on feature data calculated from each of the plurality of defect data pieces; and
visualizing representative data extracted from each group and presenting the visualized representative data to a user.
